(19) United States
(12) Patent Application Publication
(10) Pub. No.: US 2023/0060609 A1
(43) Pub. Date: Mar. 2, 2023

(54) WAFER CARRIER ASSEMBLY WITH PEDESTAL AND COVER RESTRAINT ARRANGEMENTS THAT CONTROL THERMAL GAPS

(71) Applicant: Veeco Instruments Inc., Plainview, NY (US)

(72) Inventors: Sandeep Krishnan, Princeton Junction, NJ (US); Bojan Mitrovic, Basking Ridge, NJ (US); Eric A. Armour, Pennington, NJ (US); Yuliy Rashkovsky, Millburn, NJ (US); Robert S. Maxwell, IV, Brooklyn, NY (US); Matthew J. Van Doren, Roxbury, CT (US)

(21) Appl. No.: 17/462,990

(22) Filed: Aug. 31, 2021

(51) Int. Cl. H01L 21/677; H01L 21/205; H01L 21/687; C23C 16/46

(52) U.S. Cl. CPC H01L 21/67763; H01L 21/205; H01L 21/6875; H01L 21/68785; C23C 16/46; H01L 21/0262

(57) ABSTRACT

A wafer carrier assembly as described herein improves thermal control across a top surface thereof to maintain highly controlled deposition locations and thicknesses.

### TECHNICAL FIELD

The present disclosure relates generally to semiconductor fabrication technology. More particularly, the present disclosure relates to a wafer carrier assembly for a chemical vapor deposition (CVD) reactor with pedestal and cover restraint having ledge arrangements that control thermal gaps to improve the management of thermal uniformity during the CVD process.

### BACKGROUND

Certain processes for fabrication of semiconductors can require a complex process for growing epitaxial layers to create multilayer semiconductor structures for use in fabrication of high performance devices, such as light emitting diodes (LEDs), laser diodes, optical detectors, power electronics, and field effect transistors. In this process, the epitaxial layers are grown through a general process called Chemical Vapor Deposition (CVD). One type of CVD process is called Metal Organic Chemical Vapor Deposition (MOCVD). In MOCVD, reactant gases are introduced into a sealed reactor chamber within a controlled environment that enables the reactor gas to be deposited on a substrate (commonly referred to as a wafer) to grow thin epitaxial layers. Examples of current product lines for such manufacturing equipment include the TurboDisc®, MaxBright®, and EPIK® families of MOCVD systems, and the PROPEL® Power GaN MOCVD system, all manufactured by Veeco Instruments Inc. of Plainview, N.Y.

During epitaxial layer growth, a number of process parameters are controlled, such as temperature, pressure, and gas flow rate, to achieve desired quality in the epitaxial layers. Different layers are grown using different materials and process parameters. For example, devices formed from compound semiconductors such as III-V semiconductors, typically are formed by growing a series of distinct layers. In this process, the wafers are exposed to a combination of reactant gases, typically including a metal organic compound formed using an alkyl source including a group III metal such as gallium, indium, aluminum, and combinations thereof, and a hydride source including a Group V element such as NH3, AsH3, PH3, or an Sb metalorganic, such as tetramethyl antimony. Generally, the alkyl and hydride sources are combined with a carrier gas, such as N2 and/or H2, which does not participate appreciably in the reaction. In these processes, the alkyl and hydride sources flow over the surface of the wafer and react with one another to form a III-V compound of the general formula In_{X}Ga_{Y}Al_{Z}N_{A}As_{B}P_{C}Sb_{D}, where x+y+z equals approximately one, A+B+C+D equals approximately one, and each of x, y, z, A, B, C, and D can be between zero and one. In other processes, commonly referred to as “halide” or “chloride” processes, the Group III metal source is a volatile halide of the metal or metals most commonly a chloride such as GaCl2. In yet other processes, bismuth is used in place of some or all of the other Group III metals.

A suitable substrate for the reaction can be in the form of a wafer having metallic, semiconducting, and/or insulating properties. In some processes, the wafer can be formed of sapphire, aluminum oxide, silicon (Si), silicon carbide (SiC), gallium arsenide (GaAs), indium phosphide (InP), indium arsenide (InAs), gallium phosphide (GaP), aluminum nitride (AlN), silicon dioxide (SiO2), and the like.

In a CVD process chamber, one or more wafers are positioned within a tray, commonly referred to as a wafer carrier, so that the top surface of each wafer is exposed, thereby providing a uniform exposure of the top surface of the wafer to the atmosphere within the reactor chamber for the deposition of semiconductor materials. The wafer carrier is commonly rotated at a rotation speed on the order from about 50 to 1500 RPM or higher. While the wafer carrier is rotated, the reactant gases are introduced into the chamber from a gas distribution device, positioned upstream of the wafer carrier. The flowing gases pass downstream toward the wafer carrier and wafers, desirably in a laminar flow. One such example of a CVD process chamber is disclosed in U.S. Pat. No. 10,570,510, the contents of which are hereby incorporated by reference herein. The wafer carrier includes a carrier element having pockets for the semiconductor wafers, commonly referred to as a susceptor or platen or base, that is typically formed of a single bulk material such as graphite or silicon carbide. In various embodiments, wafer carriers can include cover restraints positioned above the susceptor or platen or base to aid in defining the pockets and retaining the wafers within the pockets. Various configurations and shapes of susceptors/platens/bases and cover restraints have been developed to improve processing as shown, for example, in U.S. Pat. No. 8,888,919.

During the CVD process, the wafer carrier is maintained at a desired elevated temperature by heating elements, often positioned beneath the wafer carrier. Therefore, heat is transferred from the heating elements to the bottom surface of the wafer carrier and flows upwardly through the wafer carrier to the one or more wafers. Depending on the process, the temperature of the wafer carrier is maintained on the order of between 700-1200° C. The reactive gases, however, are introduced into the chamber by the gas distribution device at a much lower temperature, typically 200° C., or lower, so as to inhibit premature reaction of the gases.

In such an environment, it is generally desirable to maintain highly uniform deposition rates for the material or materials that are epitaxially grown. More uniform thicknesses of the wafer or constituent layers within the wafer results in lower waste or unusable product. In a conventional chemical vapor deposition system that incorporates a thermal cover, heat is transferred from the susceptor/platen/base to the wafer substrates directly while the thermal transfer to the cover is reduced. A typical system will have a temperature difference of about 30° C. between the wafers and the substrate itself, and temperatures within the wafers can vary in a range of about 3-4° C., but even these small variations can impact wafer uniformity and increase deposition times. Reduced waste product comes with a reduced amount of reactor operation time to create a desired quantity of wafer material, which can provide substantial economic benefit. Additionally, reduced waste results in lower material costs and need for proper recycling or disposal of the waste.

In addition to enhancing deposition uniformity, it is generally beneficial to avoid deposition in locations other than substrates, as buildup over time can cause changes in the flow path across the surface of the wafers, as well as eventually building up to sufficient thickness that deposited material can dislodge and disturb samples that are being deposited on the base. Typically, surfaces in the CVD reactor that are not designed for deposition are cleaned after a certain amount of runtime, and the longer between cleanings the better to avoid system downtime.

It would be desirable to provide improvements to wafer carriers that would enhance uniformity in deposition rates resulting in improved deposition layer uniformity due to reduced thermal deviations while also reducing excess deposition buildup.

### SUMMARY

According to a first embodiment, a wafer carrier assembly is described for use in a system for growing epitaxial layers on one or more wafers by chemical vapor deposition (CVD). The wafer carrier assembly includes a base including a generally planar bottom surface that is situated perpendicularly to a central axis, and a top surface that is generally parallel to the bottom surface. In embodiments, the base includes a plurality of pedestals and a plurality of platforms extending from the top surface. A thermal cover defines a plurality of pockets that each can contain a wafer substrate and are arranged such that each pocket of the plurality of pockets is adjacent to a platform of the plurality of platforms when the thermal cover is coupled to the base. In embodiments, the thermal cover further defines at least one ledge at each of the plurality of pockets. In embodiments, the thermal cover is coupled to the base and restrained from thermally induced movement by a set of cover restraints. The pedestals and the platforms of the base and the ledges of the thermal cover are configured and sized such that a wafer substrate arranged to define a set of thermal gaps that improve the management of thermal uniformity during the CVD process.

In some embodiments, the thermal cover is configured to have a relatively larger offset from the base at the ledge than at the pedestals. The pedestals can be the only physical connection between the thermal cover and the substrate. The wafer carrier assembly can include a substrate arranged on the ledge. The thermal cover can include a radially outer edge portion that extends away from the base. The base can include a radially outer edge portion that extends from the top surface. The wafer carrier assembly can include a plurality of pins configured to couple the base and the thermal cover.

The above summary is not intended to describe each illustrated embodiment or every implementation of the subject matter hereof. The figures and the detailed description that follow more particularly exemplify various embodiments.

### BRIEF DESCRIPTION OF THE DRAWINGS

Subject matter hereof may be more completely understood in consideration of the following detailed description of various embodiments in connection with the accompanying figures, in which:

FIG. 1 is a perspective view of a wafer carrier assembly according to an embodiment.

FIG. 2 is a top view of the wafer carrier assembly of FIG. 1.

FIG. 3 is an exploded view of the wafer carrier assembly of FIGS. 1 and 2.

FIGS. 4A and 4B are detailed views of a wafer carrier assembly according to an embodiment.

FIG. 5 is a cross-sectional, detailed view of a wafer carrier assembly according to an embodiment.

FIG. 6 is a cross-sectional view of a pin according to an embodiment.

FIGS. 7A and 7B are cross-sectional views of a pocket at a radially outer edge of a wafer carrier assembly according to two embodiments.

While various embodiments are amenable to various modifications and alternative forms, specifics thereof have been shown by way of example in the drawings and will be described in detail. It should be understood, however, that the intention is not to limit the claimed inventions to the particular embodiments described. On the contrary, the intention is to cover all modifications, equivalents, and alternatives falling within the spirit and scope of the subject matter as defined by the claims.

### DETAILED DESCRIPTION OF THE DRAWINGS

Embodiments described herein provide several improvements, some or all of which may individually or in combination may be applicable to the different embodiments, and each of which is described in more detail below. First, use of pedestals and platforms and thermal cover ledges as described herein provides for targeted setting of the extent of thermal coupling between components thereof, including the ability to manage thermal couplings for different wafer and/or deposition materials. Second, the use of different materials and fasteners described herein prevents deformation of the thermal cover during deposition (or over the course of several deposition processes), which in turn improves uniformity of the product made by a reactor over the long term. Third, the specific arrangements of components described herein enhances wafer thickness uniformity and facilitates the creation of wafers having thin, tightly-defined layers. Fourth, thermal control structures described herein provide tunable temperature profiles across the top surface of a base and thermal cover, preventing epitaxial growth in areas where it is undesirable and therefore reducing the amount of reactor downtime and cleaning time required.

In various combinations and configurations, these improvements can reduce wafer bow sensitivity. In embodiments, selective use of thermal gaps and/or coupling can reduce wafer temperature gradients such that pockets can be arranged more closely to one another.

Throughout the application, several terms that are known to those of skill in the art of chemical vapor deposition and similar systems are used. These terms may differ, in some cases, from the plain and ordinary meaning of those terms in common parlance. As used throughout this application, the following terms are defined as follows:

A base is a structure arranged in a reactor to receive the precursor gases. A base may have a variety of pockets defined therein, upon which wafers are grown. In embodiments, substrates are positioned within each of the pockets and the wafer is grown, via epitaxial growth in the reactor chamber, upon these substrates.

During growth of the wafers, the base is typically both heated and spun, along with the rest of the wafer carrier assembly. Heating provides energy to promote reaction of the precursor gases incident upon the substrates in the wafer carrier assembly, while spinning the wafer carrier assembly promotes uniformity of growth throughout the wafer.

A thermal cover is a structure that can be connected to a base. The thermal cover typically covers those portions of the base other than the pockets, such that the precursor gases can still access those pockets (and/or the wafers and bases that may be positioned therein).

Pedestals and platforms, while having similar meanings in everyday use, are defined herein to refer to different structures. A platform, as used herein, refers to a raised portion that is relatively large compared to a pedestal. A platform is arranged beneath a wafer or substrate and defines a height relative to the portions of the base that are not beneath a wafer or substrate. Pedestals, on the other hand, provide support for components (e.g., substrates, thermal covers) but are small enough to provide sufficient mechanical support without promoting any significant level of thermal transfer.

Throughout this application, directions may also be referred to. When one component is referred to as being “above” or “below” another, this refers to the typical orientation in which such systems are used. In a typical chemical vapor deposition system, a showerhead or other sprayer for precursor chemical is arranged at the gravitational top of the reactor chamber. The wafer carrier assembly therefore has a thermal cover at the uppermost portion thereof. The heater is typically located below the base, or in some embodiments within the base of the wafer carrier assembly. It should be understood that this directional language is used to refer to typical systems, but that alternative chemical vapor deposition or other epitaxial growth systems could be arranged differently. These directions are therefore used for ease of discussion of the drawings and common implementations and should not be construed as limiting on the invention as described herein.

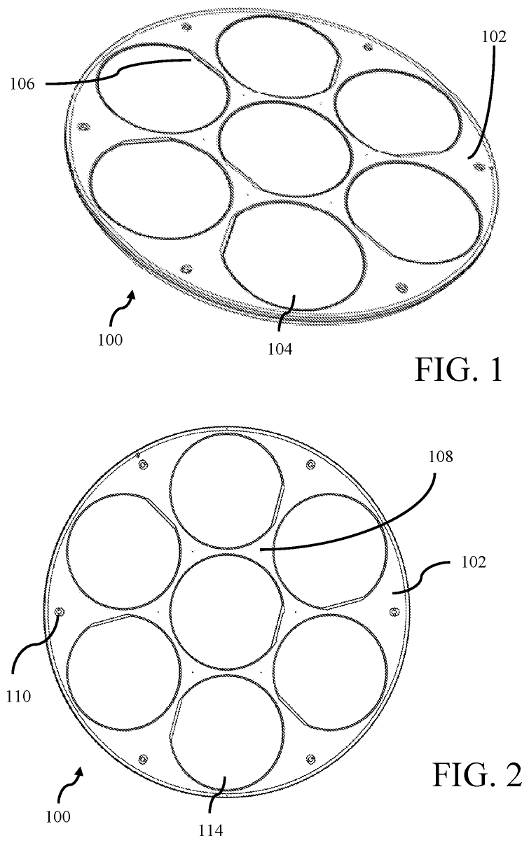

FIGS. 1 and 2 are a perspective view and a top view, respectively, of a wafer carrier assembly 100 having a thermal cover 102, according to an embodiment. As shown in FIG. 1, the wafer carrier assembly 100 includes a plurality of pockets 104, each of which corresponds to an aperture defined by the thermal cover 102. As shown most clearly in FIG. 1, each of the pockets 104 defines a flat 106. Flats 106 can be used in chemical vapor deposition systems to lock a wafer (not shown) within the corresponding pocket 104 from rotation during epitaxial growth.

As indicated in FIG. 2, the surface of the thermal cover 102 includes six holes 108. As described below in more detail, holes 108 are small protrusions through which fastening pins can be driven. Additionally, FIGS. 1 and 2 show multiple screws 110 that are used to fasten the thermal cover 102 to the wafer carrier assembly 100.

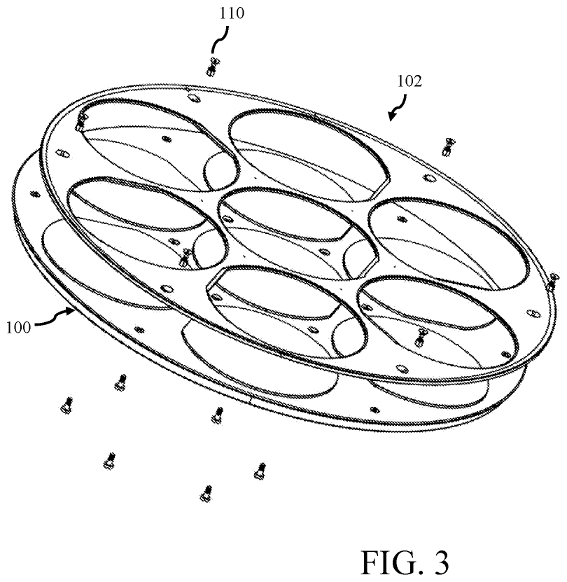

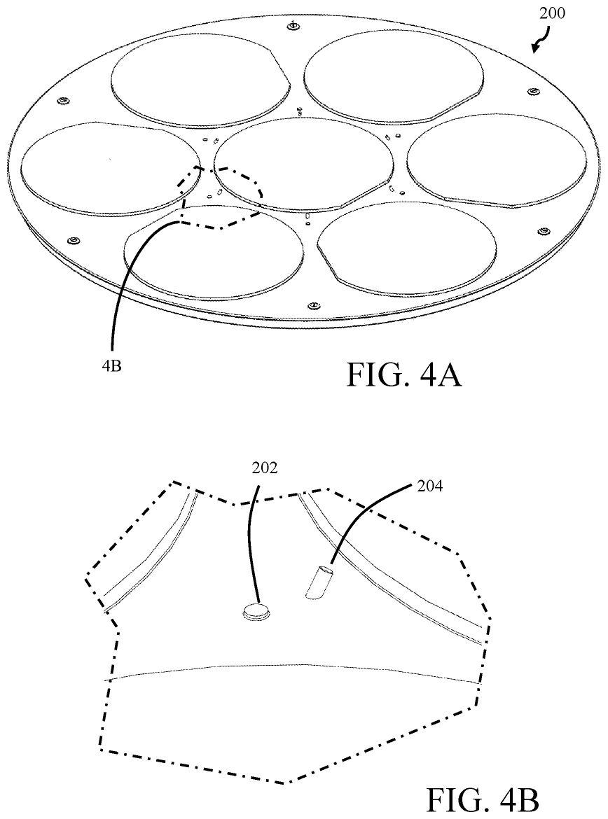

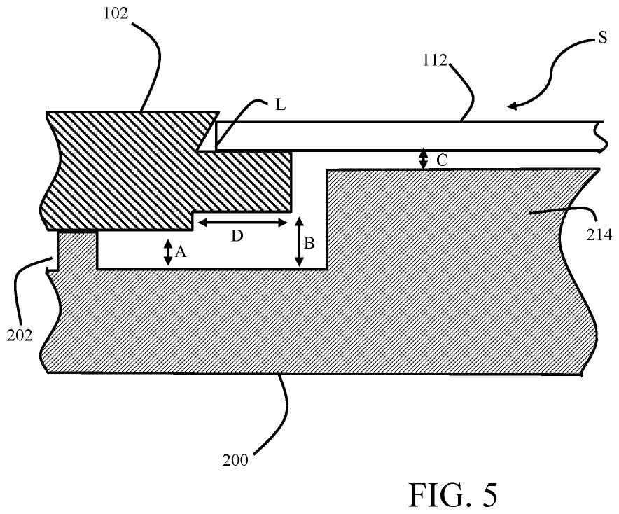

In the embodiments shown herein, pins can be used in combination with screws to accomplish a desired level of restraint. Not all of the various implementations of this concept are shown herein, but it should be understood that outer restraints are often screws, while radially inner restraints can be either angled pins or screws, to achieve a desired result. For example FIG. 3 shows a ‘pin-less’ manifestation using backside screws to keep cover fastened on the inside (not pins like FIG. 4). By going in from the backside in various embodiments, thermal imprints on the topside can be minimized or eliminated using either screws or pins. Any combination of restraints, properly positioned, using pins and screws, can be effective to prevent deformation of the cover that results in temperature non-uniformity.

In general, during epitaxial growth of a substance in a CVD system, wafer carrier assembly 100 is positioned in a reactor chamber and heated from beneath—that is, from the opposite side from the pockets 104. The chamber is generally under vacuum, with some gases introduced from one or more sources directed towards the wafer carrier assembly 100 such that it flows across the top surface thereof. The gases can include purge gases and one or more precursor gases that will react, when heated, to deposit a desired material in the pockets 104.

During a typical CVD process, it is desirable to produce growth at the pockets 104 in a manner that is uniform, predictable, and consistent from run to run. It is also desirable to reduce the amount of system time required to create each wafer, whether by increasing run speed or by reducing system downtime. System downtime can be required for cleaning, for example, when unwanted material deposition occurs where it is not desired.

However, thermal covers 102 can introduce other variables that negatively impact the ability to create uniform, predictable, and consistent growth across the pockets 104. For example, if surfaces of wafers sitting above pockets 104 are significantly hotter or colder than the surrounding thermal cover 102, as is the case for conventional single-piece wafer carriers, then gases flowing across the surface of the wafer carrier assembly 100 can exhibit temperature gradients and result in non-uniform deposition. In contrast, as described herein, thermal covers can prevent such temperature disparities, or can be used to tune the temperature disparities as desired by adjustment of the thermal gaps between the component parts thereof.

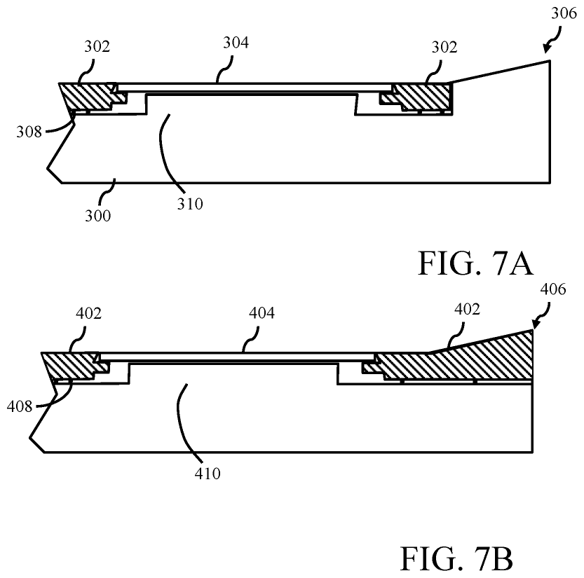

Likewise, thermal cover 102 can present physical obstructions to the flow of precursor gases that affect the quality of epitaxial growth at the pockets 104. Rotation of the wafer carrier assembly 100 during deposition generally improves uniformity and maintains uniformity between the various pockets therein. However, deformation of the thermal cover can affect space between parts of the wafer carrier assembly, which in turn affects heat transfer characteristics of the overall device. With these characteristics affected by unwanted deformation, different areas may be hotter or colder and deposition rates and patterns can be affected. These patterns result in uneven deposition and non-uniform thicknesses, and so are generally not desired (though they can be present at outer edges or other select locations, as described herein with respect to FIGS. 7A and 7B for example). To that end, it is beneficial to control deformations of the thermal cover 102 (FIGS. 1-3, 5) to maintain a generally flat, uniform surface that is not significantly dished/bowl-shaped or bowed/hilltop-shaped relative to a plane representing the ideal flat, uniform surface.

FIG. 3 is an exploded view of the wafer carrier assembly 100 and thermal cover 102 of FIGS. 1 and 2. In the exploded view, the thermal cover 102 is removed from the wafer carrier assembly 100 to show the various screws 110 that hold the thermal cover 102 to the base. It should be understood that in various embodiments, the number and arrangement of screws 110 could vary. Additionally or alternatively, the type of fastener could vary between embodiments, such that screws 110 could include counterpart nuts or washers, or could be a rivet, clasp, or other similar structure.

FIGS. 4A and 4B show structures that are useful in preventing deformation of the thermal cover of a wafer carrier, according to an embodiment. FIG. 4A shows a base 200 that is configured to engage with a thermal cover (not shown). As shown in FIG. 4A, there are several protruding structures arranged around the center of the base, indicated by the callout 4B.

FIG. 4B shows this region in more detail. Within region 4B, there are two different types of structures that improve upon conventional wafer carrier assemblies. The first of these is a pedestal 202, and the second is a pin 204. There are a plurality of both pedestals 202 and pins 204 throughout the wafer carrier assembly 100, as shown in FIG. 3.

In use of the wafer carrier assembly, pedestal 202 provides a support for the thermal cover corresponding thereto. By arranging pedestals 202 around the surface of the base 200 where the thermal cover (not shown) is to be arranged, the amount of conductive heat transfer from base 200 to thermal cover can be minimized. This provides significant benefits because the temperature of the thermal cover can therefore be kept significantly lower than that of the pockets. Pedestals 202 therefore reduce the temperature of the thermal cover, and the height of pedestals 202 can be selected to tune the temperature profile across the top surface of a wafer carrier assembly and thermal cover during use. By making pedestals 202 relatively tall, the amount of heat transferred to the thermal cover decreases, such that higher pedestals 202 makes for a cooler top surface of the thermal cover. Thermal management using pedestals will be described in more detail below with respect to FIG. 5.

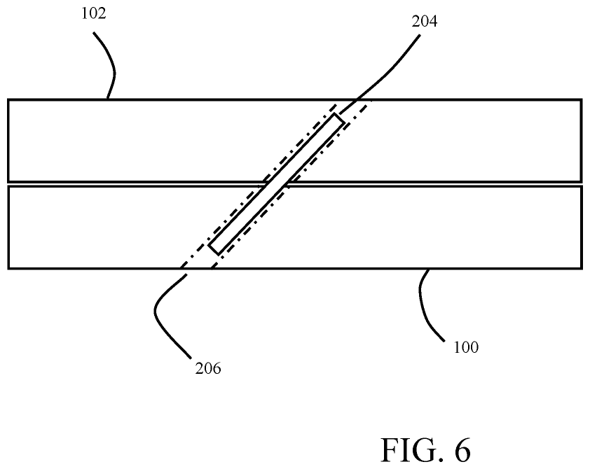

The entire wafer carrier assembly in FIG. 5 can be used as a system for growing epitaxial layers on one or more wafers by CVD or similar epitaxial growth systems. The wafer carrier assembly 100 is arranged about a central axis as shown in FIGS. 1-3 and defines a generally planar bottom surface that is situated perpendicularly to the central axis. A top surface generally parallel to the bottom surface (FIGS. 1-3) extends across the entire wafer carrier assembly 100, and a plurality of pedestals (e.g., 202) and a plurality of platforms (e.g., 214) extend upwards therefrom. A thermal cover 102 defines a plurality of pockets (see FIGS. 1-3), and the thermal cover 102 is configured to be coupled to the base by fasteners (e.g., 110 of FIGS. 1-3). The plurality of pockets are arranged such that each pocket of the plurality of pockets is adjacent to a platform of the plurality of platforms 214 when the thermal cover is coupled to the base (see FIG. 3). The thermal cover 102 further defines a ledge L at each of the plurality of pockets that can support a substrate 112. The pedestals 202, the dimensions of the thermal cover 102, and the platforms 114 are sized such that a substrate 112 arranged on the ledge L is arranged closer to its corresponding platform 114 (at dimension C) than the thermal cover 102 is from the top surface (at dimension A). Pins 204 are used to hold base 200 to its corresponding thermal cover 102 during use. Pins 204 extend from base 200 at an angle to prevent relative movement between the base 200 and a corresponding thermal cover 102, as described in more detail with respect to FIG. 6.

Pins 204 can prevent deformation of the thermal cover during or after an epitaxial growth process. Referring to FIGS. 1-3, it can be seen that the thermal cover 102 includes several portions that have a relatively thin cross-section. During growth of the wafers, spinning of the thermal cover 102 causes centripetal forces along the body of the thermal cover 102. Additionally, any buildup of material that grows on the thermal cover 102 can increase this applied force.

Furthermore, depending on the material that is being grown, the material itself can produce forces that generate planar deformation of the thermal cover. For some materials, the forces produced by the material warp the thermal cover towards a concave, “bowl” arrangement where the center is lowest, and the radially outermost edges are pushed upwards relative to the remainder of the plane of the cover. For other materials, the forces produced by the material warp the thermal cover towards a convex, “hilltop” arrangement where the center is raised, and the radially outermost edges are pushed down, relative to the remainder of the plane of the cover. Both of these “bowl” and “hilltop” planar deformation shapes are undesirable, because they affect the distance between the center vs. the edge of the thermal cover relative to the heated base of the wafer carrier assembly. Additionally, they can affect the flowpath of precursor gases across the surface formed by the substrates/wafers, susceptor, and thermal cover or they can affect the gap distance and the corresponding thermal gradient between the substrates/wafers, susceptor, and thermal cover.

Pins 204, in cooperation with screws (e.g., screws 110 of FIG. 3) prevent such planar deformations. As shown in FIG. 3, screws 110 are arranged substantially towards the radially outermost edge of wafer carrier assembly 100 and thermal cover 102. As used herein, “substantially” refers to close enough to that radially outermost edge to prevent unwanted flexing of the thermal cover 102 upwards and away from wafer carrier assembly 100 during routine epitaxial growth and rotation conditions. Likewise, pins 204 prevent the “hilltop” deformation by restricting movement of the thermal cover 102 away from the wafer carrier assembly 100.

In embodiments, the pins 204 and the screws, nuts, or other fasteners used to maintain a relatively fixed relationship between the components described herein can be made from like materials in order to prevent stresses or movement due to differences in coefficients of thermal expansion. For example, in one embodiment the screws (110, FIGS. 1-3) and pins (204, FIG. 4B) are made of carbon-carbon, as is the thermal cover 102. In other embodiments, pins 204 can be made from molybdenum or another material capable of withstanding the processing conditions inside a chemical vapor deposition system. In some embodiments, the wafer carrier assembly (e.g., 100) can be made of a material with a similar coefficient of thermal expansion, such as silicon carbide.

As described above, screws, pins, and pedestals can be used to maintain a desired physical spacing between the various components of the systems described herein. FIG. 5 shows a simplified cross-sectional view of three components of an embodiment: a wafer carrier assembly 100, a thermal cover 102, and a substrate 112.

As shown in FIG. 5, the wafer carrier assembly 100 includes a pedestal 202 that mechanically supports a thermal cover 102. In a typical embodiment, there can be a plurality of pedestals 202 that hold the thermal cover 102. Thermal cover 102 in turn mechanically supports substrate 112, upon which a wafer can be grown.

In addition to the pedestal 202, wafer carrier assembly 100 defines platform 214. Platform 214 can be sized and shaped to be substantially the same as substrate 112, in embodiments. As shown in FIG. 3, for example, the pedestals extend from the rest of the wafer carrier assembly 100 in a direction towards the thermal cover 102.

FIG. 5 depicts three different dimensions, labeled A, B, and C. Each of these dimensions is tunable as desired to create a thermal profile. By adjusting the height of the pedestals 202, the dimension A can be modified. Dimension A affects the amount of conductive thermal transfer from wafer carrier assembly 100 to the thermal cover 102. Thermal cover 102 can be shaped to have a relatively larger offset from the base 200 at a portion that supports the substrate 112, shown as dimension B. By increasing this distance, thermal transfer from wafer carrier assembly 100 to substrate 112 via the thermal cover 102 is reduced. Finally, by adjusting the height of the platform 114, dimension C can be adjusted. Increasing the dimension C results in reduced thermal transfer from wafer carrier assembly 100 to substrate 112, while a lower dimension C will increase thermal transfer.

Dimension D corresponds to a cutout portion for which the gap B exists between the thermal cover 102 and the base 200 of the wafer carrier assembly. Put another way, dimension D is the amount that a supporting portion of the thermal cover 102 extends towards the platforms 214. Put yet another way, the dimension D is the amount that the bulk of the thermal cover 102 is set back from the platform 214. Dimension D, and its counterpart dimension B, provide a mechanical function (that is, supporting the substrate 112) but also determine a thermal characteristic of the overall system. As described above, the closer the thermal cover 102 is to the base 200, the higher the level of thermal coupling between those two components. By increasing D or B, the level of thermal coupling decreases. Conversely, by decreasing dimension B or dimension D, the level of thermal coupling between base 200 and thermal cover 102 increases. These dimensions can therefore be adjusted, modified, and tuned to result in a desired thermal profile at the edge of the substrate 112.

It should be understood that instead of a square cutout having linear dimensions B and D, other thermal covers 102 could have a bottom surface that is beveled, chamfered, or otherwise shaped to selectively enhance or decrease thermal transfer between the thermal cover 102 and the base 200, substrate 112, and platforms 214. In general, maintaining a constant temperature across a top surface S is desirable, including at the interface between substrate 112 and thermal cover 102, but edge effects may be desirable in some scenarios such that a hot edge or cold edge to the substrate 112 provides advantages in specialized applications.

In many systems, it is preferable to have substrate 112 hotter than the top surface of the thermal cover 102, and it is also desirable for the substrate 112 to have a very uniform temperature at the top surface. The arrangement in FIG. 5 accomplishes this goal in several ways.

First, there is no direct physical contact between the substrate 112 and the wafer carrier assembly 100. The only conductive heat transfer in the scheme of FIG. 5 is through pedestals 202 to conduct heat from wafer carrier assembly 100 to thermal cover 102. Even this conductive heat transfer is quite limited, due to the small size and number of the pedestals (see FIG. 4A). Therefore, the predominant thermal transfer mechanism in the system depicted in FIG. 5 is not conductive but rather radiative and convective. Additionally, most chemical vapor deposition systems operate in a vacuum environment such convective heat transfer is reduced as well.

In such an environment, the distance between two components has a significant effect on the amount of heat transferred therebetween. Adjusting one or more of the dimensions A, B, C, and/or D can therefore ensure that the temperature at the top surface of the thermal cover 102 is relatively low, compared to the temperature at the top surface of the substrate 112, which is usually desirable. By adjusting the amount that the wafer carrier assembly 100 is heated, the dimensions A, B, C and/or D, and the materials that make up each part, almost any desired top-surface temperature profile can be achieved.

It should be noted that the absence of pedestals 202 between the platform 114 and the substrate 112, such that conductive heat transfer does not occur between the thermal cover 102 and the substrate 112. Conductive heat transfer can create temperature variability, so eliminating this mode of thermal contact provides some benefits in terms of top-surface temperature uniformity of the substrate 112.

During epitaxial growth, the temperature at the wafer carrier assembly 100 is hot enough to cause interaction between precursor gases and corresponding epitaxial growth. However, the quantity of fluid flow between wafer carrier assembly 100 and thermal cover 102 and/or substrate 112 is very low. Therefore, the amount of growth in between these components is also low, because there is not sufficient fresh precursor gas to support continued growth. Furthermore, during a typical cycle, a chamber will first be brought into a vacuum condition, after which purge gas is introduced to the chamber. Therefore, the majority of the space between wafer carrier assembly 100 and the thermal cover 102 and/or substrate 112 is filled with purge gas, and not with the precursor material that would be capable of supporting deposition.

FIG. 6 is a detailed view of a pin 204 connecting a thermal cover 102 to a substrate 100. As shown in FIG. 6, pin 204 is angled to prevent thermal cover 102 from being lifted away from substrate 100. As is apparent from FIG. 5, such lifting could affect the dimensions A, B, and C, making each of these larger towards the center of the wafer carrier assembly 100 and smaller at the radially outer portions thereof.

FIGS. 7A and 7B show two embodiments of a system for epitaxial growth at a radially outer edge thereof. As described in U.S. Pat. No. 8,888,919, for example, a raised or inclined radially outer edge can provide a more laminar flowpath for precursor gas that is directed across a wafer carrier assembly. As shown in FIGS. 7A and 7B, this feature can be implemented with the embodiments described above either by building up such a radially outer edge as a part of the wafer carrier assembly base, or as a part of the thermal cover.

As shown in FIG. 7A, a wafer carrier assembly 300 holds a thermal cover 302, which in turn holds a substrate 304. The wafer carrier assembly 300 includes a radially outer edge portion 306, which is angled upwards. This angled portion can maintain better laminar flow of precursor gases across the substrate 304 during deposition. As further shown in FIG. 7A, relatively small pedestals 308 support the thermal cover 302, while a larger platform 310 extends to almost contact substrate 304.

FIG. 7B shows a similar, alternative embodiment. As shown in FIG. 7B, a wafer carrier assembly 400 holds a thermal cover 402, which in turn holds a substrate 404. The thermal cover 402 includes a radially outer edge portion 406, which is angled upwards. This angled portion can maintain better laminar flow of precursor gases across the substrate 404 during deposition. As further shown in FIG. 7B, relatively small pedestals 408 support the thermal cover 402, while a larger platform 410 extends to almost contact substrate 404.

As described above, the pedestals (e.g., 202) and platforms (e.g., 114) can be sized and arranged to set the extent of thermal coupling in the overall system. In this way, the top surface (and the only surface at which significant epitaxial growth occurs) can have a temperature profile that is designed to cause uniform and targeted growth. That is, layers can be grown with high levels of thickness uniformity and predominantly on the substrate (e.g., 112) rather than occurring elsewhere (such as on the thermal cover 102). Furthermore, the fasteners described herein are arranged and made of materials such that forces caused by thermal expansion and contraction, or forces caused by deposited material itself, do not significantly affect the standoff distances between the various components. Because the standoff distances are not affected significantly, the heat transfer is also not affected significantly.

Taken together, these improvements can be particularly beneficial for systems that are designed to make thin multi-layer constructions. Such structures often have a high waste or scrap rate because thickness non-uniformity is unacceptable for some applications. Maintaining uniform temperature (and therefore thickness) results in reduced waste or scrap and is therefore commercially beneficial.

Various embodiments of systems, devices, and methods have been described herein. These embodiments are given only by way of example and are not intended to limit the scope of the claimed inventions. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the claimed inventions.

Persons of ordinary skill in the relevant arts will recognize that the subject matter hereof may comprise fewer features than illustrated in any individual embodiment described above. The embodiments described herein are not meant to be an exhaustive presentation of the ways in which the various features of the subject matter hereof may be combined. Accordingly, the embodiments are not mutually exclusive combinations of features; rather, the various embodiments can comprise a combination of different individual features selected from different individual embodiments, as understood by persons of ordinary skill in the art. Moreover, elements described with respect to one embodiment can be implemented in other embodiments even when not described in such embodiments unless otherwise noted.

Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims, it is expressly intended that the provisions of 35 U.S.C. § 112(f) are not to be invoked unless the specific terms “means for” or “step for” are recited in a claim.

1. A wafer carrier assembly for use in a system for growing epitaxial layers on one or more wafers by chemical vapor deposition (CVD), the wafer carrier assembly comprising:
a base including a generally planar bottom surface and a top surface that is generally parallel to the bottom surface, wherein the top surface further includes a plurality of pedestals and a plurality of platforms extending above the top surface; and
a thermal cover defining a plurality of pockets, wherein the thermal cover is configured to be coupled to the base by at least one fastener and the plurality of pockets are arranged such that each pocket of the plurality of pockets is aligned with a corresponding platform of the plurality of platforms when the thermal cover is supported by the plurality of pedestals of the base, the thermal cover further defining an edge portion having a reduced thickness proximate each of the plurality of pockets on which the wafer for that pocket is carried;
wherein the pedestals and the platforms of the wafer carrier and the edge portion of the thermal cover are sized such that a set of thermal control gaps are defined that maintain a desired thermal profile along the top surface of the wafer carrier assembly.

2. The wafer carrier assembly of claim 1, wherein a wafer positioned in a pocket of the plurality of pockets is arranged above the corresponding platform of the pocket at a distance that is less than a height of the pedestals relative to the top surface.

3. The wafer carrier assembly of claim 1, wherein the edge portion of the thermal cover is shaped to have a rectangular cutout portion.

4. The wafer carrier assembly of claim 1, wherein the pedestals are the only physical connection between the thermal cover and the substrate.

5. The wafer carrier assembly of claim 1, wherein the thermal cover includes a radially outer edge portion that extends away from the base.

6. The wafer carrier assembly of claim 1, wherein the base includes a radially outer edge portion that extends from the top surface.

7. The wafer carrier assembly of claim 1, further comprising a plurality of pins configured to couple the base and the thermal cover.

8. The wafer carrier assembly of claim 7, wherein the plurality of pins are inserted at an angle relative to the top surface of the wafer carrier assembly.

9. The wafer carrier assembly of claim 1, wherein the desired thermal profile is uniform.
